(19) United States
(12) Patent Application Publication
(10) Pub. No.: US 2007/0190233 A1
(43) Pub. Date: Aug. 16, 2007

(54) APPARATUS AND METHOD FOR MANUFACTURING A DISPLAY DEVICE

(75) Inventor: Jin-koo Chung, Suwon-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (KR)

(21) Appl. No.: 11/674,475

(22) Filed: Feb. 13, 2007

(30) Foreign Application Priority Data
Feb. 15, 2006 (KR) 10-2006-0014578

(51) Int. Cl. B05D 5/12; B05B 7/06; B05D 7/00

(52) U.S. Cl. 427/58; 347/40; 118/313; 427/402

(57) ABSTRACT

An apparatus for manufacturing a display device which includes an insulating substrate and a plurality of sub-pixels provided in a substantially matrix shape on the insulating substrate, each pixel having a pixel electrode exposing region, the apparatus including; a nozzle coater which includes a plurality of sub-nozzle coaters arranged substantially in a row along a predetermined first direction and which drops ink onto the pixel electrode exposing region while moving along a second direction substantially perpendicular to the first direction, and an interval adjusting part which adjusts an interval between the sub-nozzle coaters.

This application claims priority to Korean Patent Application No. 2006-0014578, filed on Feb. 15, 2006, and all the benefits accruing therefrom under 35 U.S.C. §119, the contents of which in its entirety are herein incorporated by reference.

### BACKGROUND OF THE INVENTION

1. Field of the Invention

The present invention relates to an apparatus and a method for manufacturing a display device, and more particularly, to an apparatus and a method for manufacturing a display device which successively drops ink to form a certain material layer in a predetermined region of a substrate.

2. Description of the Related Art

An organic light emitting diode (“OLED”) display has increased in popularity as a flat panel display because of its low-power requirements, light weight, slim shape, wide viewing angle, high-speed response, and other positive attributes.

In the OLED display, thin film transistors (“TFT”) are connected to sub-pixel regions, thereby controlling light emission of light emitting layers which are formed in each sub-pixel region to emit light of a different color. A pixel electrode exposing region is provided in each sub-pixel region to expose an upper portion of a pixel electrode. An organic layer, possibly including a hole injecting layer and a light emitting layer, is formed in the pixel electrode exposing region.

The organic layer is generally formed by an ink-jet method. In the ink-jet method, an organic layer forming material is dissolved in an ink and the ink is intermittently dropped onto each pixel electrode exposing region through a nozzle of a jetting member, after which the ink is dried to form the organic layer.

However, intermittently dropping the ink requires a large amount of time. Also, maintaining proper performance of the nozzle so as to intermittently and smoothly drop the ink is not easy. Thus, the ink may spatter out of the pixel electrode exposing region or be dropped excessively or insufficiently, thereby inducing a defective sub-pixel and an inferior quality display.

To overcome this problem a method has been introduced in which ink is successively dropped to a plurality of pixel electrode exposing regions along a line of sub-pixels, wherein each sub-pixel emits the same color. Such a successive ink dropping method employs a nozzle coater including a nozzle. However, when the nozzle coater has only one nozzle, a large amount of time is still required to drop the ink to the pixel electrode exposing regions across the entire display.

Furthermore, when the nozzle coater has a plurality of nozzles an interval between the nozzles is fixed, and thus it is not easy to adjust the interval between the nozzle coaters corresponding to the size of the sub-pixel and the size and locations of the pixel electrode exposing regions as may be necessary in order to manufacture displays with different pixel dimensions.

### BRIEF SUMMARY OF THE INVENTION

Accordingly, it is an aspect of the present invention to provide an apparatus and a method for manufacturing a display device which are capable of quickly and accurately forming a certain material layer in a predetermined region of a substrate.

An exemplary embodiment of an apparatus for manufacturing a display device which includes a substrate including an insulating substrate and a plurality of sub-pixels provided in a substantially matrix shape on the insulating substrate, each pixel having a pixel electrode exposing region, the apparatus including; a nozzle coater which includes a plurality of sub-nozzle coaters arranged substantially in a row along a predetermined first direction and which drops ink onto the pixel electrode exposing region while moving along a second direction substantially perpendicular to the first direction, and an interval adjusting part which adjusts an interval between the sub-nozzle coaters.

According to an exemplary embodiment of the present invention a plurality of gate lines and data lines are insulated from and intersect each other on the substrate, the first direction is substantially parallel to a lengthwise direction of the gate lines, and the second direction is substantially parallel to a lengthwise direction of the data lines.

According to an exemplary embodiment of the present invention, the plurality of sub-nozzle coaters drop ink including an organic layer forming material onto the pixel electrode exposing region.

According to an exemplary embodiment of the present invention the organic layer forming material includes one of a hole injecting layer forming material, a hole transfer layer forming material and an electron transfer layer forming material.

According to an exemplary embodiment of the present invention, the nozzle coater includes; a first sub-nozzle coater which drops a first ink including an organic red light emitting layer forming material, a second sub-nozzle coater which drops a second ink including an organic green light emitting layer forming material, and a third sub-nozzle coater which drops a third ink including an organic blue light emitting layer forming material.

According to an exemplary embodiment of the present invention, the interval adjusting part adjusts the interval between the sub-nozzle coaters according to the equation d=a×m±b, wherein d is the interval between the sub-nozzle coaters, a is a length of the sub-pixels in the first direction, m is a natural number greater than 2, and b is less than about 40% of the length of one of the sub-pixels in the first direction.

According to an exemplary embodiment of the present invention, the interval adjusting part adjusts the interval between the sub-nozzle coaters according to the equation d=3a×n+c, wherein d is the interval between the sub-nozzle coaters, a is a length of the sub-pixels in the first direction, n is a natural number, and c is about 80% to about 120% of the interval between central points of adjacent pixel electrode exposing regions in the first direction.

According to an exemplary embodiment of the present invention, the interval adjusting part adjusts the interval between the sub-nozzle coaters to dispose the sub-nozzle coaters within 20% of a width of the sub-pixel from central positions of the sub-pixels in the first direction.

An exemplary embodiment of a method for manufacturing a display device includes; providing a substrate which includes an insulating substrate and a plurality of sub-pixels disposed substantially in a matrix on the insulating substrate and each sub-pixel having a pixel electrode exposing region, arranging a plurality of sub-nozzle coaters in a row along a predetermined first direction, adjusting an interval between the sub-nozzle coaters, and dropping ink from the plurality of sub-nozzle coaters onto the pixel electrode exposing region while the sub-nozzle coaters move along a second direction substantially perpendicular to the first direction.

According to an exemplary embodiment of the present invention, a plurality of gate lines and data lines are insulated from and intersect each other on the substrate, the first direction is substantially parallel to a lengthwise direction of the gate lines, and the second direction is substantially parallel to a lengthwise direction of the data lines.

According to an exemplary embodiment of the present invention, the dropping ink from the plurality of sub-nozzle coaters includes dropping an organic layer forming material onto the pixel electrode exposing region.

According to an exemplary embodiment of the present invention the dropping an organic layer forming material further comprises dropping one of a hole injecting layer forming layer, a hole transfer layer forming material and an electron transfer layer forming material.

According to an exemplary embodiment of the present invention, the plurality of sub-nozzle coaters comprises; a first sub-nozzle coater which drops a first ink including an organic red light emitting layer forming material, a second sub-nozzle coater which drops a second ink including an organic green light emitting layer forming material, and a third sub-nozzle coater which drops a third ink including an organic blue light emitting layer forming material.

According to an exemplary embodiment of the present invention, the adjusting an interval between the sub-nozzle coaters further comprises; adjusting the interval between the sub-nozzle coaters according to the equation d=a×m±b, wherein d is the interval between the sub-nozzle coaters, a is a length of the sub-pixels in the first direction, m is a natural number greater than 2, and b is less than about 40% of the length of the sub-pixels in the first direction.

According to an exemplary embodiment of the present invention, the adjusting an interval between the sub-nozzle coaters further includes; adjusting the interval between the sub-nozzle coaters according to the equation d=3a×n+c, wherein d is the interval between the sub-nozzle coaters, a is a length of the sub-pixels in the first direction, n is a natural number, and c is about 80% to about 120% of the interval between central points of adjacent pixel electrode exposing regions in the first direction.

According to an exemplary embodiment of the present invention, the adjusting an interval between the sub-nozzle coaters further includes disposing the central positions of the sub-nozzle coaters within 20% of a width of the sub-pixel from central positions of the sub-pixels in the first direction.

### BRIEF DESCRIPTION OF THE DRAWINGS

The above and/or other aspects, features and advantages of the present invention will become apparent and more readily appreciated from the following description of the exemplary embodiments, taken in conjunction with the accompanying drawings, in which:

FIG. 1 is an equivalent circuit diagram of an exemplary embodiment of a sub-pixel of an exemplary embodiment of a display device manufactured by an exemplary embodiment of an apparatus according to the present invention;

FIG. 2 is a top plan view of an exemplary embodiment of the display device manufactured by the exemplary embodiment of an apparatus according to the present invention;

FIG. 3 is a cross-sectional view of the exemplary embodiment of a display device manufactured by the exemplary embodiment of an apparatus according to the present invention;

FIG. 4 is a front perspective view of a first exemplary embodiment of an apparatus for manufacturing an exemplary embodiment of a display device according to the present invention;

FIG. 5 is a cross-sectional view of the first exemplary embodiment of an apparatus for manufacturing the display device according to the present invention;

FIG. 6 is a flow chart illustrating an exemplary embodiment of a method for manufacturing an exemplary embodiment of a display device using the first exemplary embodiment of an apparatus according to the present invention;

FIG. 7 is a top plan view of an exemplary embodiment of a display device illustrating an exemplary embodiment of a method for manufacturing the display device using the first exemplary embodiment of an apparatus according to the present invention;

FIG. 8 is a top plan view of an exemplary embodiment of a display device illustrating a second exemplary embodiment of a method for manufacturing an exemplary embodiment of a display device using the first exemplary embodiment of an apparatus according to the present invention;

FIG. 9 is a top plan view of an exemplary embodiment of a display device illustrating a third exemplary embodiment of a method for manufacturing an exemplary embodiment of a display device using the first exemplary embodiment of an apparatus according to the present invention;

FIG. 10 is a cross-sectional view of a second exemplary embodiment of an apparatus for manufacturing an exemplary embodiment of a display device according to the present invention; and

FIG. 11 is a flow chart sequentially illustrating an exemplary embodiment of a method for manufacturing an exemplary embodiment of a display device using the second exemplary embodiment of an apparatus according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present, As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in more detail with reference to the accompanying drawings.

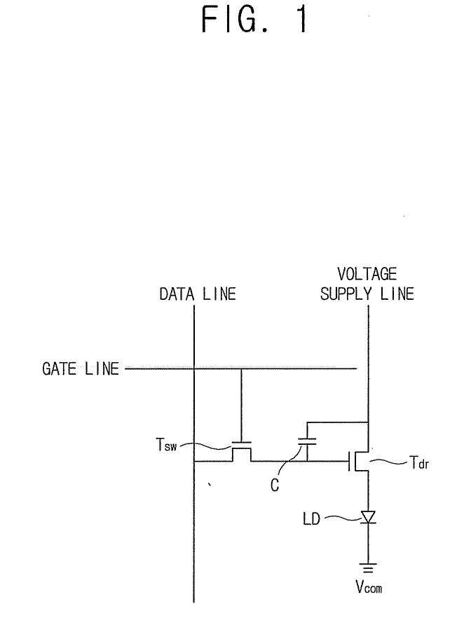

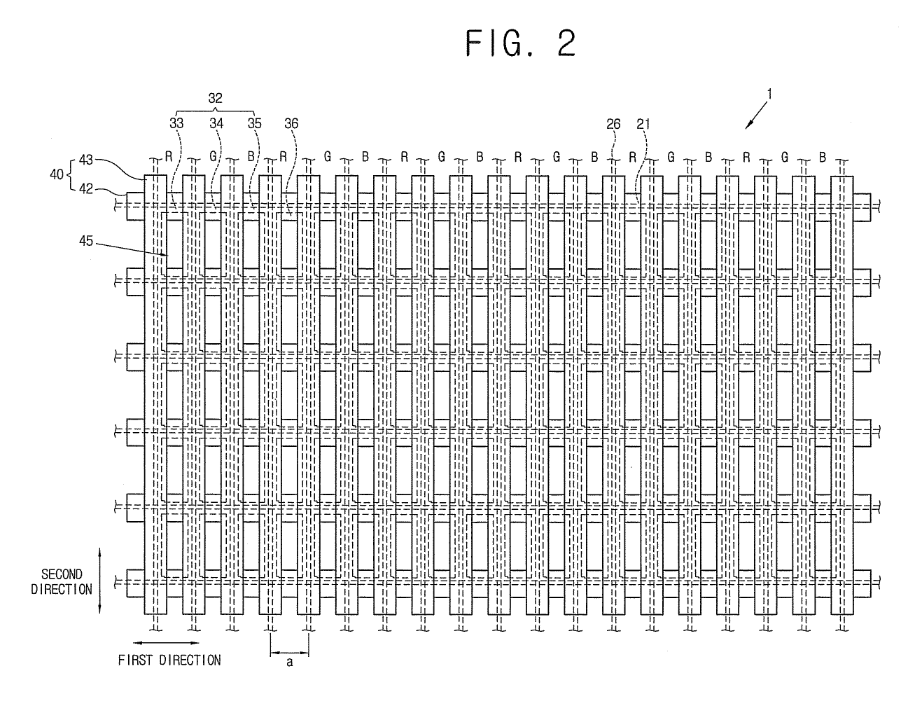

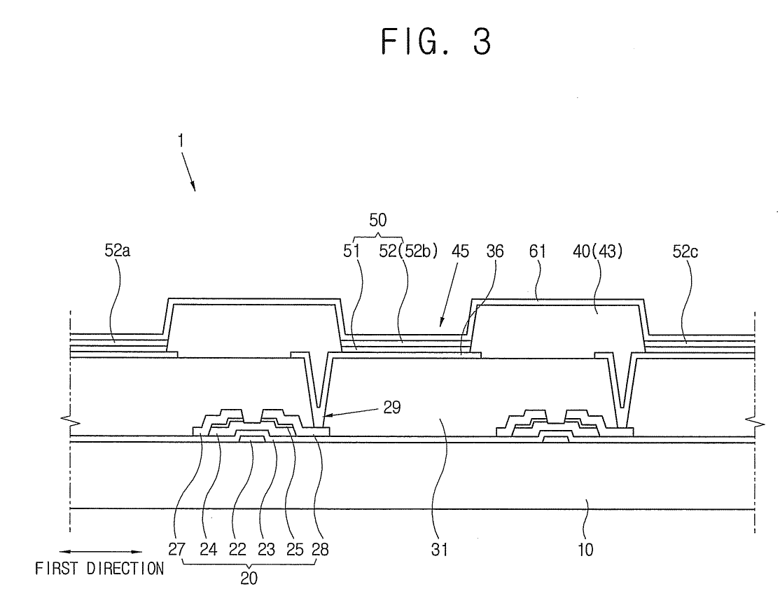

An exemplary embodiment of an organic light emitting diode (“OLED”) will be described in with reference to FIGS. 1 through 3. FIG. 1 is an equivalent circuit diagram of an exemplary embodiment of a sub-pixel of an exemplary embodiment of a display device manufactured by an exemplary embodiment of an apparatus according to exemplary embodiments of the present invention. FIG. 2 is a front top plan view of an exemplary embodiment of the display device manufactured by the exemplary embodiment of an apparatus according to the exemplary embodiments of the present invention. FIG. 3 is a schematic cross-sectional view of the exemplary embodiment of a display device manufactured by the exemplary embodiment of an apparatus according to the exemplary embodiments of the present invention

Referring to FIG. 1, one sub-pixel comprises a plurality of signal lines. The signal lines comprise a gate line transmitting a scanning signal, a data line transmitting a data signal and a power supply line transmitting a driving voltage. In this exemplary embodiment of an OLED display the data line and the power supply line are disposed substantially adjacent and parallel to each other. The gate line extends substantially perpendicularly to the data line and the power supply line.

Each sub-pixel comprises an organic light emitting element LD, a switching thin film transistor Tsw, a driving thin film transistor Tdr and a capacitor C.

The driving thin film transistor Tdr comprises a control terminal, an input terminal and an output terminal. The control terminal is connected to the switching thin film transistor Tsw, the input terminal is connected to the power supply line, and the output terminal is connected to the organic light emitting element LD.

The organic light emitting element LD comprises an anode connected to the output terminal of the driving thin film transistor Tdr and a cathode connected to the common voltage Vcom. The organic light emitting element LD emits light with a variable intensity depending on an output current from the driving thing film transistor Tdr. The intensity of the current from the driving thin film transistor Tdr varies depending on a voltage between the control terminal and the output terminal. A plurality of pixels, each including a light emitting element LD may be used to display images.

The switching thin film transistor Tsw comprises a control terminal, an input terminal and an output terminal. The control terminal is connected to the gate line, the input terminal is connected to the data line, and the output terminal is connected to the control terminal of the driving thin film transistor Tdr. The switching thin film transistor Tsw transmits the data signal of the data line to the driving thin film transistor Tdr according to the scanning signal applied to the gate line.

The capacitor C is connected between the control terminal of the driving thin film transistor Tdr and the input terminal thereof. The capacitor C is charged with and maintains the data signal input to the control terminal of the driving thin film transistor Tdr.

Referring to FIGS. 2 and 3, the display device 1 comprises an insulating substrate 10 and a plurality of gate lines 21 and data lines 26 which are formed on the insulating substrate 10. The gate lines 21 and the data lines 26 are insulated from and cross over or under each other.

Accordingly, the exemplary embodiment of a display device 1 comprises a plurality of sub-pixels 33, 34 and 35 formed substantially in a matrix due to the intersecting nature of the gate lines 21 and the data lines 26.

A first sub-pixel 33 includes a red light emitting layer 52a; a second sub-pixel 34 includes a green light emitting layer 52b; and a third sub-pixel 35 includes a blue light emitting layer 52c. The first, second and third sub-pixels 33, 34 and 35 are alternately formed in the pixel electrode exposing region 45 in a first direction, e.g., a direction substantially parallel to the gate lines 21. A plurality of first sub-pixels 33, second sub-pixels 34 and third sub-pixels 35 each are disposed in a row along a second direction, e.g., a direction of the data lines 26. In the resulting display, a plurality of lines are created wherein each line of sub-pixels, each sub-pixel in the line emitting the same color, is disposed along the second direction and the color of light emitted by each line alternates along the first direction.

One pixel 32 comprises a neighboring set including one of the first sub-pixels 33, one of the second sub-pixels 34 and one of the third sub-pixels 35.

A pixel electrode 36 is formed in each of the sub-pixels 33, 34 and 35, and the pixel electrode exposing region 45 is formed in the sub-pixels 33, 34 and 35 to expose a portion of the pixel electrode 36. In one exemplary embodiment the pixel electrode exposing region 45 has a relatively wide area in order to increase an aperture ratio of the resulting display device 1. In one exemplary embodiment the area of the pixel electrode exposing region 45 in each of the sub-pixels is less than about 60% of the area of each of sub-pixels 33, 34 and 35 considering the sizes of the gate lines 21, the data lines 26, a TFT 20, a wall 40, and other components of the sub-pixel, all of which consume space therein. In one exemplary embodiment, the pixel electrode exposing region 45 is formed in the middle of each sub-pixel 33, 34 and 35, however alternative exemplary embodiments include configurations wherein the pixel electrode exposing region 45 may be formed toward one side or another of the sub-pixel 33, 34 and 35 in either the first or second directions considering an arrangement of the signal lines 21 and 22.

In the current exemplary embodiment each of the sub-pixels 33, 34 and 35 has a shorter length in the first direction than in the second direction, and the pixel electrode exposing region 45 also has a shorter length in the first direction than that in the second direction.

The wall 40 is formed on the gate lines 21, the data lines 26 and the pixel electrode 36 but is not formed on, or is removed from, the pixel electrode exposing region 45. The wall 40 comprises a first wall 42 formed in the first direction and a second wall 43 formed in the second direction.

An organic layer 50 and a common electrode 61 will be described in more detail below with reference to FIG. 3. The organic layer 50 is formed on the pixel electrode exposing region 45, and the common electrode 61 is formed on the organic layer 50 and the wall 40.

Referring to FIG. 3, the display device 1 comprises the insulating substrate 10, the TFT 20 formed on the insulating substrate 10, the pixel electrode 36 electrically connected to the TFT 20, the wall 40 formed on the pixel electrode 36, the organic layer 50 formed in the pixel electrode exposing region 45 which is not covered by the wall 40, and the common electrode 61 formed on the organic layer 50.

In one exemplary embodiment the insulating substrate 10 is made of an insulating material such as quartz, ceramic or plastic, and a portion of the gate line 21 (see FIG. 2) is formed as a gate electrode 22 on the insulating substrate 10.

A gate insulating layer 23, an exemplary embodiment of which is made of silicon nitride (“SiNx”) or other similar materials, is formed on the insulating substrate 10 and the gate electrode 22. A semiconductor layer 24, one exemplary embodiment of which is made of amorphous silicon, is formed on the gate insulating layer 23. Then, an ohmic contact layer 25, an exemplary embodiment of which is made of n+hydrogenated amorphous silicon which is highly doped with n-type impurities, is formed on the semiconductor layer 24. The ohmic contact layer 25 is divided into two parts about the gate electrode 22.

A source electrode 27 and a drain electrode 28 are branched from the data line 26 and formed on the ohmic contact layer 25 and the gate insulating layer 23. The source electrode 27 and the drain electrode 28 are spaced apart from each other with the gate electrode 22 disposed therebetween. A passivation layer 31 is formed on the source electrode 27, the drain electrode 28, and portions of the semiconductor layer 24 and ohmic contact layer 25 exposed between the source and drain electrodes 27 and 28. In one exemplary embodiment the passivation layer 31 may be made of silicon nitride (“SiNx”), an organic layer, or a combination of the two. A contact hole 29 is formed in the passivation layer 31 to expose the drain electrode 28.

The pixel electrode 36 is formed on the passivation layer 31. The pixel electrode 36 is called an anode and provides holes to the light emitting layer 52. Exemplary embodiments of the pixel electrode 36 include indium tin oxide (“ITO”) or indium zinc oxide (“IZO”) and in one exemplary embodiment the pixel electrode 36 is formed by a sputtering method.

The wall 40 has a latticed shape and is formed on the pixel electrode 36 and the passivation layer 31. The wall 40 comprises the first wall 42 formed in the first direction and the second wall 43 formed in the second direction 43, however, only the second wall 43 is shown in FIG. 3. In the present exemplary embodiment the second wall 43 is formed higher than the first wall 42 so that ink may be successively dropped into the plurality of pixel electrode exposing regions 45 disposed along the second direction in the line of each of the sub-pixels 33, 34 and 35 without difficulty. In the present exemplary embodiment the higher walls 43 ensure that there is no mixing of ink from a sub-pixel of one color into another, the lower walls 42 are less important for preventing color mixing since they separate sub-pixels of the same color.

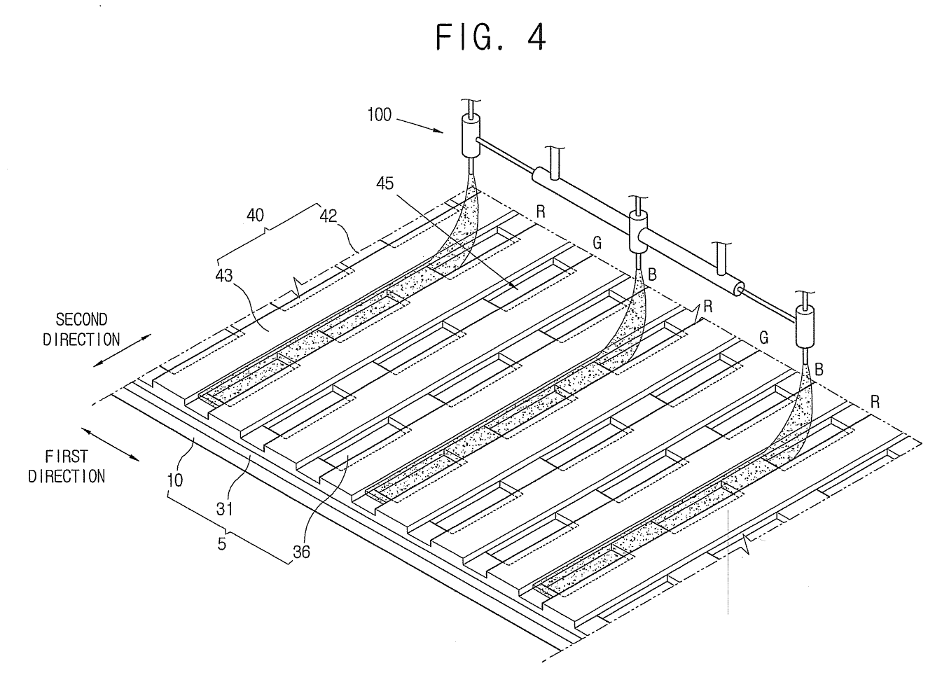

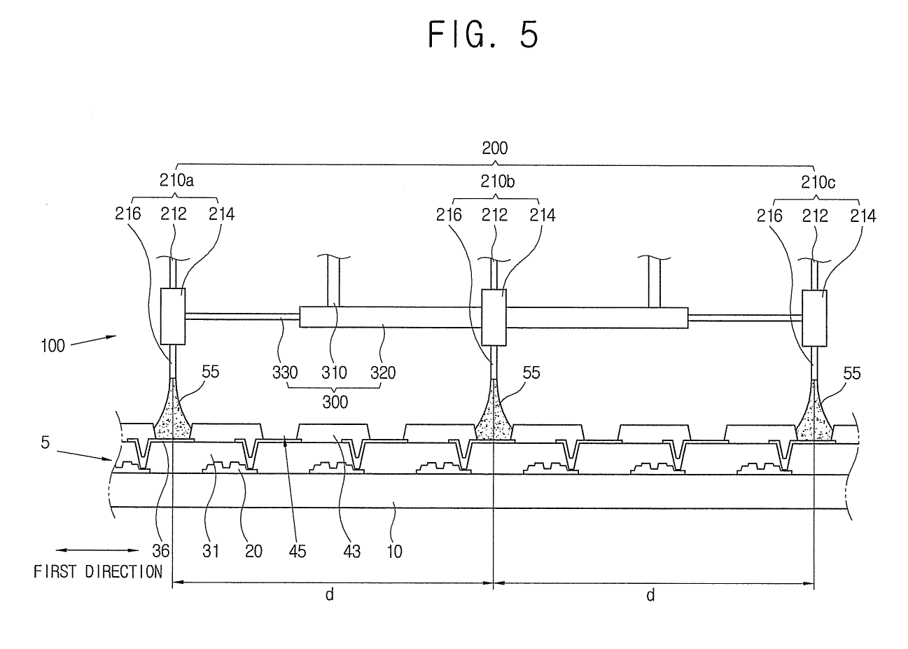

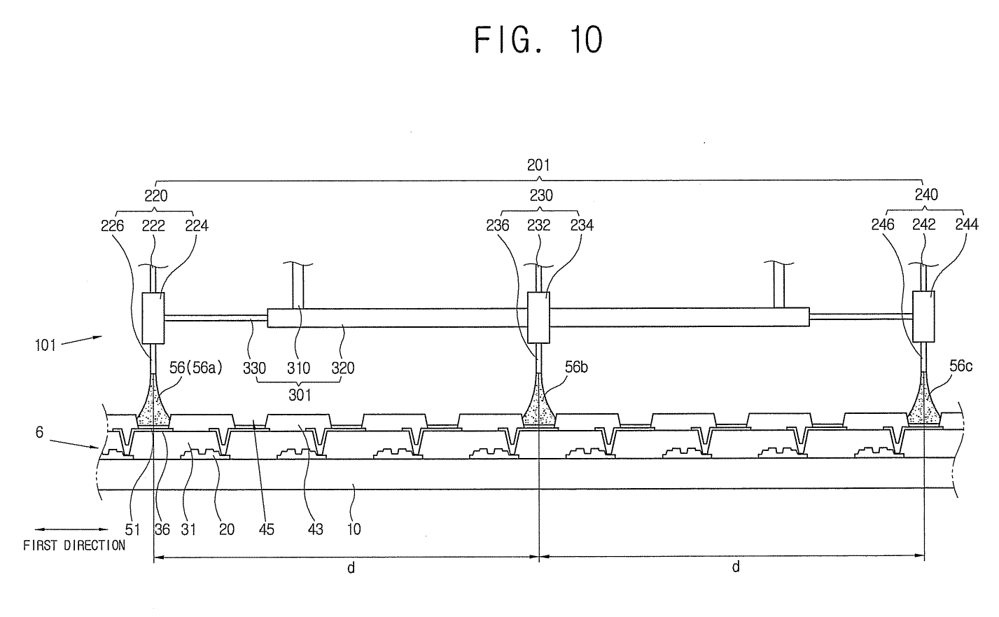

The organic layer 50 is formed in the pixel electrode exposing region 45 on a portion of the pixel electrode 36 which is not covered with the wall 40. In one exemplary embodiment the organic layer 50 comprises a hole injecting layer 51 and a light emitting layer 52. At least one of the hole injecting layer 51 and the light emitting layer 52 is formed by a nozzle coater such as element 200 in the apparatus 100 of FIGS. 4 and 5 and element 201 in the apparatus 101 of FIG. 10 for manufacturing the display device according to the present invention as will be discussed in more detail below.

In one exemplary embodiment the hole injecting layer 51 may be formed with an ink 55 (referring to FIG. 4) made of a polythiophene derivative such as poly-3,4-ethylenedioxythiophene (“PEDOT”) and poly styrenesulfonate (“PSS”).

The light emitting layer 52 comprises a red light emitting layer 52a, a green light emitting layer 52b and a blue light emitting layer 52c.

In one exemplary embodiment the light emitting layer 52 is formed with an ink 56 (referring to FIG. 10) made of polyfluorene derivatives, poly(p-phenylene vinylene) derivatives, polyphenylene derivatives, poly(N-vinylcarbazole) derivatives and poly thiophene derivatives or compounds thereof doped with a perillene group pigment, rhodamine, rubrene, perillene, 9,10-diphenylanthracene, tetraphenylbutadiene, nile red, cumarine 6, quinacridone, or various other similar substances.

The common electrode 61 is formed on the wall 40 and the light emitting layer 52. The common electrode 61 is called a cathode and provides electrons to the light emitting layer 52.

In one exemplary embodiment the common electrode 61 is made of an opaque material such as aluminum or silver, and light emitted from the light emitting layer 52 exits toward the insulating substrate 10. Such a configuration is known as a bottom emission type display.

In one exemplary embodiment the organic layer 50 may further comprise at least one of a hole transfer layer (not shown) between the hole injecting layer 51 and the light emitting layer 52, and an electron transfer layer (not shown) and an electron injection layer (not shown) between the light emitting layer 52 and the common electrode 61. Furthermore, the organic layer 50 may further comprise an interlayer.

The various components of the organic layer 50, including the light emitting layer 52, may be formed by dropping ink made of a low molecular weight organic substance. Furthermore, the organic layer 50 may further comprise a passivation layer to protect the common electrode 61 and an encapsulation member (not shown) to prevent moisture and air from infiltrating thereinto.

Hereinafter, a first exemplary embodiment of an apparatus for manufacturing the exemplary embodiment of a display device according to the present invention will be described with reference to FIGS. 4 and 5. FIG. 4 is a front perspective view of a first exemplary embodiment of an apparatus for manufacturing an exemplary embodiment of a display device according to a first embodiment of the present invention. FIG. 5 is a cross-sectional view of the first exemplary embodiment of an apparatus for manufacturing the display device according to the first embodiment of the present invention.

As illustrated, the exemplary embodiment of an apparatus 100 for manufacturing the exemplary embodiment of a display device according to the present invention comprises a nozzle coater 200 and an interval adjusting part 300. The nozzle coater 200 comprises three sub-nozzle coaters 210a, 210b and 210c disposed in a row along the first direction. The interval adjusting part 300 adjusts an interval ‘d’ between nozzles 216 of the sub-nozzle coaters 210a, 210b and 210c.

The nozzle coater 200 forms the hole injecting layer 51 on the pixel electrode 36 in the pixel electrode exposing region 45. In the present exemplary embodiment the nozzle coater 200 successively drops ink 55 to the pixel electrode exposing region while moving along the second direction. In the above process each of the sub-nozzle coaters intermittently drops ink including a hole injecting layer forming material to the pixel electrode exposing region 45. Thus, when using the nozzle coater 200, the time required for depositing ink 55 can be decreased and the ink may be dropped with a high degree of accuracy due to the pressure in each of the nozzles 216.

The sub-nozzle coaters 210a, 210b and 210c each comprise a supplier 212 provided with the ink 55, a storage container 214 which stores the ink 55 and a nozzle 216 dropping the ink 55 in the storage container 214.

A first sub-nozzle coater 210a successively drops the ink 55 onto the pixel electrode exposing regions 45 disposed in a first sub-pixel line corresponding to a column of sub-pixels 33 of a first color while moving along the second direction.

A second sub-nozzle coater 210b is spaced apart from the first sub-nozzle coater 210a at an interval having a distance ‘d’ in the first direction and successively drops the ink 55 onto the pixel electrode exposing regions 45 disposed in another first sub-pixel line corresponding to a column of sub-pixels 33 of the same first color while moving along the second direction.

A third sub-nozzle coater 210c is spaced apart from the second sub-nozzle coater 210b by the interval d in the first direction and successively drops the ink 55 onto the pixel electrode exposing regions 45 disposed in still another first sub-pixel line corresponding to a column of sub-pixels 33 of the same first color while moving along the second direction.

In another exemplary embodiment, the sub-nozzle coaters 210a, 210b and 210c may not comprise the storage container 214, and in such an exemplary embodiment the nozzle 216 is provided with ink 55 directly from the supplier 212. In yet another exemplary embodiment, the sub-nozzle coaters 210a, 210b and 210c may comprise a storage container 214 and a nozzle 216 without the supplier 212.

The interval d between the sub-nozzle coaters 210a, 210b and 210c is adjusted by the interval adjusting part 300.

The interval adjusting part 300 comprises a pair of supporting parts 310, a pair of bodies 320 and a pair of extending parts 330.

Lower portions of the supporting parts 310 are connected to the bodies 320, and upper portions thereof are connected to a driving part (not shown). The supporting parts 310 thereby support the bodies 320, the extending parts 330 and the sub-nozzle coaters 210a, 210b and 210c. The driving part positions the interval adjusting part 300 along with a surface of a substrate 5 to be coated, and thus the nozzle coater 200 connected to the interval adjusting part 300 moves parallel with the surface of the substrate 5 for dropping the ink 55.

First portions of the bodies 320 accommodate first portions of the extending parts 330, and second portions of the bodies 320 are connected to the storage container 214 of the second sub-nozzle coater 210b.

Second portions of the extending parts 330 each are connected to the first sub-nozzle coater 210a and the third sub-nozzle coater 210c, respectively. The extending parts 330 are extendable from the bodies 320 to adjust the interval between the sub-nozzle coaters 210a, 210b and 210c.

While one exemplary embodiment has been described above, the interval adjusting part 300 may have various configurations to adjust the interval between the sub-nozzle coaters 210a, 210b and 210c.

The interval d between the sub-nozzle coaters 210a, 210b and 210c is determined by one of the following equations:

d=a×m±b Equation (1)

d=3a×n+c Equation (2).

Here, d is given as the interval between the sub-nozzle coaters 210a, 210b and 210c, e.g., an interval between central points of the nozzles 216. The variable ‘a’ is given as the length of one of the sub-pixels 33, 34 and 35 in the first direction, ‘m’ is given as a natural number greater than 2, and ‘b’ is given as less than about 40% of the length of one of the sub-pixels 33, 34 or 35 in the first direction. Furthermore, ‘n’ is given as a natural number and ‘c’ is given as about 80% to about 120% of the distance between central points of the pixel electrode exposing regions 45 which are adjacent in the first direction.

In equation (1), m should be natural number larger than 2 so that the ink 55 is dropped to the plurality of pixel electrode exposing regions 45 disposed in the sub-pixel lines which are not adjacent. That is, the adjacent sub-nozzle coaters 210a, 210b and 210c are allowed to be disposed at regular intervals over a certain distance. The sub-pixels 33, 34 and 35 each have a length of several micrometers to hundreds of micrometers in the first direction. Thus, the minimum interval between the neighboring nozzles 216 in the first direction should be at least two times the length of one of the sub-pixels 33, 34 and 35 in the first direction considering the size of the storage container 214 of the respective sub-nozzles coater 210a, 210b and 210c or other physically limiting characteristics of the nozzle coater 200.

Meanwhile, b is given as a measure of an acceptable margin of error and is less than about 40% of the length of one of the sub-pixels 33, 34 and 35 in the first direction at maximum. The acceptable margin of error should be considered, since the pixel electrode exposing region 45 may be disposed in a different location in each sub-pixel 33, 34 and 35, e.g., toward one side of the first direction considering the arrangement of the data line 26 or the second wall 43. That is, the location of the pixel electrode exposing region 45 within the pixel where the sub-nozzle coaters 210a, 210b and 210c drop the ink may vary in each sub-pixel 33, 34 and 35 to be closer to or farther away from one side or the other of the pixel along the first direction. Thus, b is determined in order to accurately drop the ink to the each pixel electrode exposing region 45 as the pixel electrode exposing region 45 may not be formed in the center of the sub-pixels 33, 34 and 35 but instead may be disposed up to 20% away from the center of the sub-pixels toward one side of the pixel in the first direction.

Equation (2) is also used to determine an interval between sub-nozzle coaters 220, 230 and 240 of a nozzle coater 201 in a second exemplary embodiment of an apparatus for manufacturing a display device according to the present invention, which will be described in more detail as follows. When the interval is determined by equation (2), a hole injecting layer 51 and a light emitting layer 52 may be formed with the ink 55 and 56 by the same dropping process.

Equation (2) will be explained in more detail in conjunction with the second exemplary apparatus for manufacturing the display device according to the present invention.

The interval adjusting part 300 adjusts the sub-nozzle coaters 210a, 210b and 210c to be disposed in a position within 20% from the central position of the sub-pixels 33, 34 and 35 with respect to the first direction as described by equations (1) or (2).

In the current exemplary embodiment, three sub-nozzle coaters 210a, 210b and 210c are provided, however equation (1) applies for configurations having two or more sub-nozzle coaters 210a, 210b and 210c. Three sub-nozzle coaters 210a, 210b and 210c as shown in FIGS. 4 and 5 for the first exemplary embodiment, or a number evenly divisible by three of sub-nozzle coaters 220, 230 and 240 as shown in FIG. 10 for the nozzle coater 201 in the apparatus 101 according to the second exemplary embodiment of the present invention should be provided. An interval between the first sub-nozzle coater 210a and the second sub-nozzle coater 210b may differ from an interval between the second sub-nozzle coater 210b and the third sub-nozzle coater 210c in order to compensate for errors as necessary.

In the first exemplary embodiment of an apparatus 100 for manufacturing the exemplary embodiment of a display device 1 according to the present invention, the nozzle coater 200 comprises the plurality of sub-nozzle coaters 210a, 210b and 210c which successively drop the ink 55 onto the pixel electrode exposing region 45, thereby improving the speed at which ink 55 may be deposited.

Furthermore, the interval between the sub-nozzle coaters 210a, 210b and 210c may be adjusted depending on the sizes of the sub-pixels 34, 35 and 36 on the display apparatus or the size and the position of the pixel electrode exposing region 45 within the pixel itself, thereby improving the accuracy of a dropping process. Thus, the hole injecting layer 55 may be quickly and accurately formed on the substrate 5.

The first exemplary embodiment of an apparatus 100 for manufacturing an exemplary embodiment of a display device apparatus 1 according to the present invention may be used to form a hole transfer layer, an electron transfer layer or other similar components of an OLED.

Hereinafter, an exemplary embodiment of a method for manufacturing an exemplary embodiment of a display device using the first exemplary embodiment of a display device manufacturing apparatus according to the present invention will be described with reference to FIGS. 4 through 9.

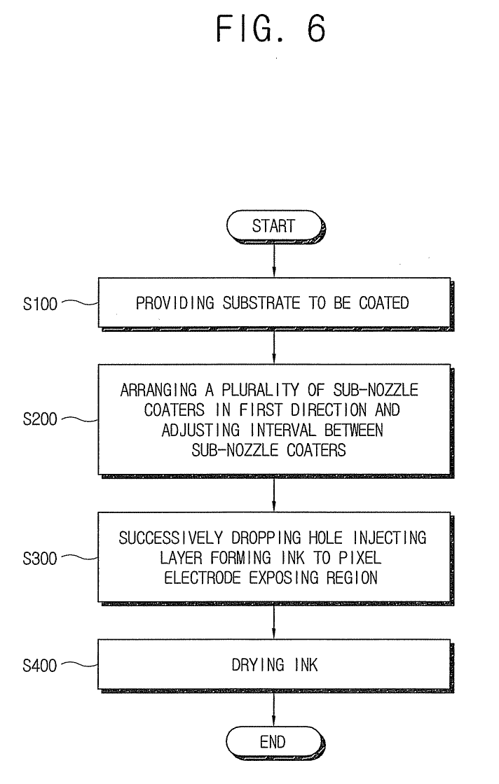

FIG. 6 is a flow chart illustrating an exemplary embodiment of a method for manufacturing an exemplary embodiment of a display device using the first exemplary embodiment of an apparatus according to the present invention.

Referring to FIG. 6, at a first block S100 the substrate 5 is provided to be coated.

As shown in FIGS. 4 and 5, the substrate 5 comprises the insulating substrate 10, the TFTs 20, the pixel electrode 36 and the wall 40 which are formed on the insulating substrate 10. The hole injecting layer 51 is formed in the pixel electrode exposing region 45 surrounded by the wall 40 on the substrate 5. The substrate 5 may be manufactured by a known method, and thus a detailed description thereof will be omitted.

At a block S200 the sub-nozzle coaters 210a, 210b and 210c of the nozzle coater 200 are arranged in a row along the first direction, and the interval d therebetween is adjusted.

In the present exemplary embodiment the first direction denotes a lengthwise direction substantially parallel to the gate line 21 formed on the insulating substrate 10. The interval d between the sub-nozzle coaters 210a, 210b and 210c may be adjusted to more accurately position each sub-nozzle coater over the pixel electrode exposing region 45. The interval d is determined by equation (1) or (2) considering the sizes of the sub-pixels 33, 34 and 35 or the size and the position of the pixel electrode exposing region 45 within each sub-pixel 33, 34 and 35.

In a next block S300 the sub-nozzle coaters 210a, 210b and 210c successively drop the ink 55 made of a hole injecting layer forming material on the plurality of pixel electrode exposing regions 45 moving along the second direction which is substantially perpendicular to the first direction.

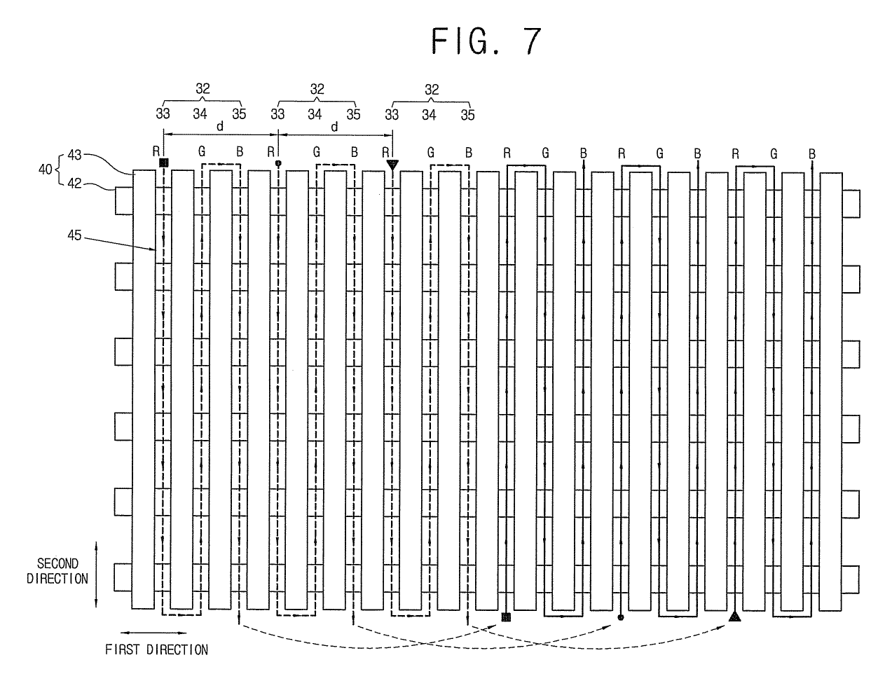

There are various methods to successively drop the ink on the entire pixel electrode exposing regions 45 of the substrate 5. One exemplary embodiment of which will be described with reference to FIG. 7 below. FIGS. 7-9 are top plan views of exemplary embodiments of a display device illustrating exemplary embodiments of a method for manufacturing the display device using the first exemplary embodiment of an apparatus according to the present invention.

Referring now to FIG. 7, the interval d between the sub-nozzle coaters 210a, 210b and 210c is adjusted so that the sub-nozzle coaters 210a, 210b and 210c may be disposed over the sub-pixels 32 in each first sub-pixel line of three different pixels 32. In the present exemplary embodiment, the interval d is determined by equation (1). The variable m is given as 3; and an error b is given as 0% of the length of one of the sub-pixels 33, 34 and 35 in the first direction in the present exemplary embodiment, but may be up to 40% thereof. Thus, the interval d becomes 3a, that is, three times as long as the length of one of the sub-pixels 33, 34 and 35 in the first direction.

The sub-nozzle coaters 210a, 210b and 210c successively drop the ink 55 onto the pixel electrode exposing regions 45 while moving downward along the second direction.

The sub-nozzle coaters 210a, 210b and 210c then move over the second sub-pixel lines 34 neighboring the first sub-pixel lines 33 along the first direction and successively drop the ink 55 onto the pixel electrode exposing regions 45 while moving upward along the second direction.

The sub-nozzle coaters 210a, 210b and 210c then move over the third sub-pixel lines 35 neighboring the second sub-pixel lines 34 along the first direction and successively drop the ink 55 onto the pixel electrode exposing regions 45 while moving downward along the second direction. Accordingly, the ink 55 can be dropped onto all of the pixel electrode exposing regions 45 in three sub-pixel lines 33, 34 and 35 corresponding to three pixels 32. The path of each sub-nozzle coater 210a, 210b and 210c is shown in FIGS. 7-9 with a different icon; the path of the first sub-nozzle coater 210a is shown starting at a square (▪), the path of the second sub-nozzle coater 210b is shown starting at a circle (), and the path of the third sub-nozzle coater 210c is shown starting at a triangle (▾).

Then, the nozzle coater 200 moves over other sub-pixel lines of the next three pixels 32 along the first direction to drop the ink 55 onto the pixel electrode exposing regions 45 and repeats the aforementioned steps, thereby completely dropping the ink 55 onto the entire pixel electrode exposing regions 45 of the substrate 5.

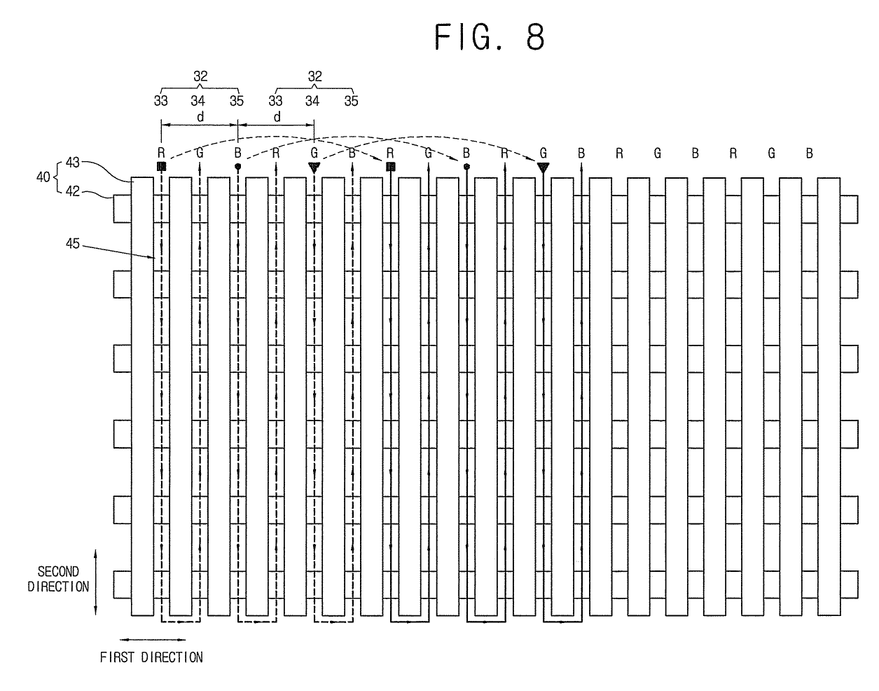

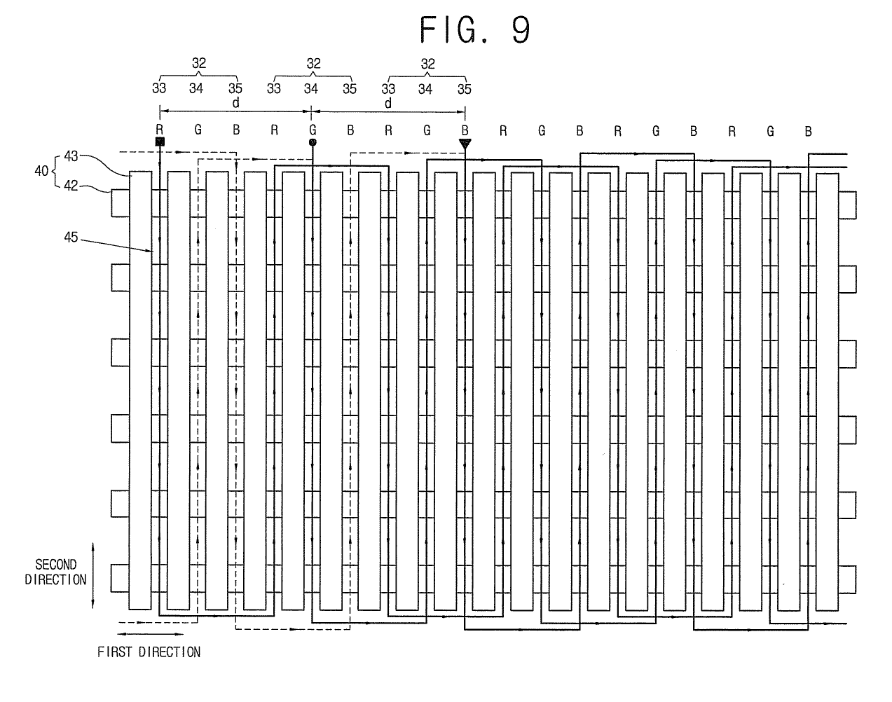

Referring to FIGS. 8 and 9, other dropping methods will be described.

In another exemplary embodiment of a dropping method as illustrated in FIG. 8, an interval d between the sub-nozzle coaters 210a, 210b and 210c is determined by equation (1). Here, m is given as 2, and an error b is 0. Thus, the interval d becomes 2a, that is, two times as long as the length of one of the sub-pixels 33, 34 and 35 in the first direction.

The interval between the sub-nozzle coaters 210a, 210b and 210c is adjusted so that the sub-nozzle coaters 210a, 210b and 210c are disposed over the sub-pixel lines 33, 34 and 35 so that there is a sub-pixel line 33, 34 or 35 between each sub-nozzle coater 210a, 210b and 210c. The sub-nozzle coaters 210a, 210b and 210c successively drop the ink 55 onto the pixel electrode exposing regions 45 while moving downward along the second direction.

The sub-nozzle coaters 210a, 210 and 210c move over to neighboring sub-pixel lines and successively drop the ink 55 onto the pixel electrode exposing regions 45 while moving upward along the second direction. Accordingly, the sub-nozzle coaters 210a, 210b and 210c completely drop the ink 55 onto the pixel electrode exposing regions 45 in six sub-pixel lines of first two pixels 32.

Then, the nozzle coater 200 moves over to the sub-pixel lines corresponding to another pair of pixels 32 which is next to the first two pixels 32 along the first direction to drop the ink 55 onto the pixel electrode exposing regions 45. By repeating the aforementioned process, the apparatus 100 may completely drop the ink 55 onto the entire pixel electrode exposing regions 45 of the substrate 5.

In a third exemplary embodiment of a dropping method as illustrated in FIG. 9, the interval d between the sub-nozzle coater 210a, 210b and 210c is determined by equation (2). In equation (2), n is given as 1; and c is given as a distance between central points of the neighboring pixel electrode exposing regions 45 in the first direction in the present exemplary embodiment. However, in alternative exemplary embodiments c may be 80% to 120% of the interval between the central points of the neighboring pixel electrode exposing regions 45. Thus, the interval d becomes 3a+c. Here, as the length a of one of the sub-pixel pixel 33, 34 and 35 in the first direction is the same as the distance c between the central points of the neighboring pixel electrode exposing regions 45 in the first direction, the interval d becomes 4a, e.g., a quadruple length or four times the length of one of the sub-pixels 33, 34 and 35.

An interval d between the sub-nozzle coaters 210a, 210b and 210c is adjusted so that the sub-nozzle coaters 210a, 210b and 210c are disposed over the first sub-pixel line 33 of a first pixel 32, the second sub-pixel line 34 of a second pixel 32, and the third sub-pixel line 35 of a third pixel 32, respectively. The sub-nozzle coaters 210a, 210b and 210c successively drop the ink 55 onto the pixel electrode exposing regions 45 while moving along the second direction.

Then, the sub-nozzle coaters 210a, 210b and 210c move over a first sub-pixel line 33 of the second pixel 32, a second sub-pixel line 34 of the third pixel 32 and a third sub-pixel line 35 of a fourth pixel 32, respectively, while maintaining the interval d therebetween. The sub-nozzle coaters 210a, 210b and 210c successively drop the ink 55 onto the pixel electrode exposing regions 45 while moving upward along the second direction.

The movement of the sub-nozzle coaters 210a, 210b and 210c are illustrated with different courses to show the moving direction of the sub-nozzle coaters 210a, 210b and 210c. The movements in the first direction are substantially aligned along a line in the first direction. With the repeated ink dropping and moving processes of the sub-nozzle coaters 210a, 210b and 210c described above, the sub-nozzle coaters 210a, 210b and 210c can drop the ink 55 onto all the pixel electrode exposing regions 45 in the substrate 5. However, while using this exemplary embodiment of a method the first two columns of pixels 32 along the starting direction of the ink 55 application will not have ink 55 deposited onto all of the sub-pixel lines therein.

Then, in the final step S400 the dropped ink 55 is dried, thereby finishing the first exemplary embodiment of a method for manufacturing the exemplary embodiment of a display device 1 using the exemplary embodiment of an apparatus 100 for manufacturing the display device 1 according to the present invention.

In the first exemplary embodiment of a method for manufacturing the display device using the exemplary embodiment of an apparatus 100 according to the present invention, the nozzle coater 200 comprises the plurality of sub-nozzle coaters 210a, 210b and 210c to successively drop the ink 55 for forming a hole injecting layer 51 in the pixel electrode exposing regions 45 on the entire substrate 5, thereby decreasing the amount of time required for deposition of the droplets. Further, the interval between the sub-nozzle coaters 210a, 210b and 210c may be adjusted to correspond to the sizes of the sub-pixels 33, 34 and 35 or the size and the position of the pixel electrode exposing region 45, thereby improving dropping accuracy. Accordingly, the hole injecting layer 51 may be promptly and accurately formed on the substrate 5.

Hereinafter, a second exemplary embodiment of an apparatus for manufacturing an exemplary embodiment of a display device according to the present invention will be described with reference to FIG. 10. Because of the similarities between the second exemplary embodiment and the first exemplary embodiment of an apparatus for manufacturing an exemplary embodiment of a display device the following description will focus on the features which differ from those of the first exemplary embodiment. FIG. 10 is a cross-sectional view of the second exemplary embodiment of an apparatus for manufacturing the exemplary embodiment of a display device according to the present invention.

The second exemplary embodiment of an apparatus 101 is employed to form a light emitting layer 52 which emits light of different colors on pixel electrode exposing regions 45 in different sub-pixel lines 33, 34 and 35 at the same time. The apparatus 101 comprises a nozzle coater 201 including three sub-nozzle coaters 220, 230 and 240 which are disposed over a substrate 6 to be coated in a first direction; and an interval adjusting part 301 adjusting an interval d between nozzles 226, 236 and 246 of the sub-nozzle coaters 220, 230 and 240.

The nozzle coater 201 is provided to form the light emitting layer 52 on a hole injecting layer 51 in the pixel electrode exposing regions 45 of the substrate 6. The light emitting layer 52 comprises a red light emitting layer 52a, a green light emitting layer 52b and a blue light emitting layer 52c which emit different colors of light. Different colored light emitting layers are formed on the pixel electrode exposing regions 45 in each sub-pixel line 33, 34 and 35. The nozzle coater 201 drops inks 56a, 56b and 56c including a red, green and blue light emitting layer forming materials onto the pixel electrode exposing regions 45 in each sub-pixel line 33, 34 and 35 at substantially the same time. Thus, the nozzle coater 201 comprises a number of sub-nozzle coaters 220, 230 and 240 wherein the number is three or a multiple of three. The sub-nozzle coaters 220, 230 and 240 drop the respective inks 56a, 56b and 56c including materials for forming light emitting layers which emit different colors of light.

The first sub-nozzle coater 220 comprises a supplier 222 provided with the ink 56a including the red light emitting layer forming material; a storage container 224 storing the ink 56a; and a nozzle 226 dropping the ink 56a stored in the storage 224. The first nozzle coater 220 successively drops the ink 56a onto a plurality of pixel electrode exposing regions 45 in the first sub-pixel line 33, while moving along the second direction.

The second sub-nozzle coater 230 is spaced apart from the first sub-nozzle coater 220 by an interval d in the first direction and successively drops the ink 56b including the green light emitting layer forming material onto a plurality of pixel electrode exposing regions 45 in the second sub-pixel line 34, while moving along the second direction.

The third sub-nozzle coater 240 is spaced from the second sub-nozzle coater 230 by the interval d in the first direction opposite to the first sub-nozzle coater 220 and successively drops the ink 56c including the blue light emitting layer forming material onto a plurality of pixel electrode exposing regions 45 in the third sub-pixel line 34, while moving along the second direction.

The interval d between the neighboring sub-nozzle coaters 220, 230 and 240 is adjusted by the interval adjusting part 301.

The interval adjusting part 301 has substantially the same configuration as that in the first exemplary embodiment, e.g., comprises two supporting parts 310, two bodies 320 and two extending parts 330.

The interval d between the sub-nozzle coaters 220, 230 and 240 adjusted by the interval adjusting part 301 is calculated using equation (2), d=3a×n+c, substantially similar to the process used in the first exemplary embodiment.

In the present exemplary embodiment, d is given as the interval between the neighboring sub-nozzle coaters 220, 230 and 240, e.g., a distance between central points of the neighboring nozzles 226, 236 and 246. The variable a is given as the length of one of the sub-pixels 33, 34 and 35 in the first direction, n is a natural number, and c is about 80% to about 120% of a distance between the central points of the neighboring pixel electrode exposing regions 45 in the first direction.

The abovementioned values given for equation (2) are determined in consideration that the inks 56a, 56b and 56c including the red, green and blue light emitting layer forming materials are dropped onto pixel electrode exposing regions 45 in the sub-pixel lines 33, 34 and 35 of different pixels 32 at the same time. Provided that c is the same as the distance between the central points of the neighboring pixel electrode exposing regions 45 in the first direction and the middles of the pixel electrode exposing regions 45 correspond to the middles of the sub-pixels 33, 34 and 35, c becomes the same as the variable a, and thus the interval d becomes 4a. However, the range of the variable c, given as about 80% to about 120% of the distance between the central points of the neighboring pixel electrode exposing regions 45, is included because the pixel electrode exposing regions 45 may be formed leaning to one side of the respective sub-pixels 33, 34 and 35 in the first direction in order to accommodate arrangements of the data lines 26, the second wall 43 or other various components of the sub-pixels 33, 34 and 35.

When the interval of the nozzle coater 201 is determined by equation (2) to be the same as the interval of the nozzle coater 200 in the first exemplary embodiment, the hole injecting layer 51 and the light emitting layer 52 may be conveniently formed by the same dropping process as that in the first exemplary embodiment.

The interval adjusting part 301 adjusts the nozzles of the sub-nozzle coaters 220, 230 and 240 to be disposed within 20% of the central position of one of the sub-pixels 33, 34 and 35 considering a position of forming the pixel electrode exposing region 45 according to equation (2).

In one exemplary embodiment an interval between the first sub-nozzle coater 220 and the second sub-nozzle coater 230 is not the same as that between the second sub-nozzle coater 230 and the third sub-nozzle coater 240, but may vary to compensate for errors.

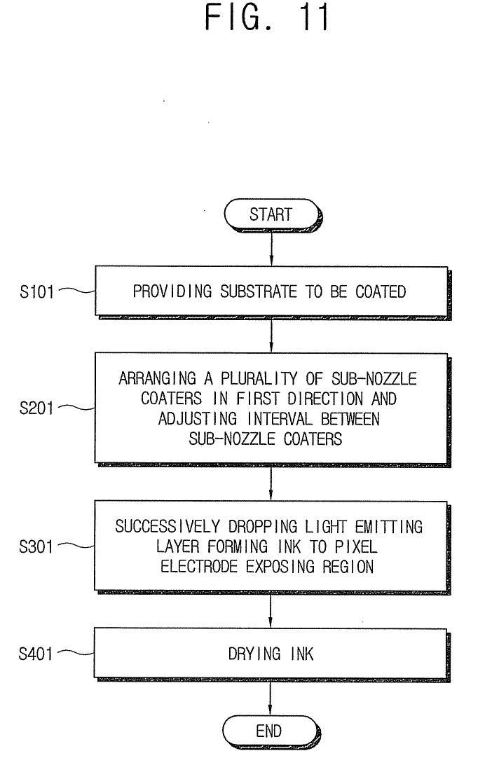

Hereinafter, an exemplary embodiment of a method for manufacturing the exemplary embodiment of a display device using the second exemplary embodiment of an apparatus 101 will be described with reference to FIGS. 10 and 11. The following description will focus on the features which differ from those of the first exemplary embodiment. FIG. 11 is a flow chart sequentially illustrating an exemplary embodiment of a method for manufacturing an exemplary embodiment of a display device using the second exemplary embodiment of an apparatus 101 according to the second embodiment of the present invention.

Referring to FIG. 11, at a first block S101 the substrate 6 to be coated is provided.

As shown in FIG. 10, the substrate 6 comprises an insulating substrate 10, a thin film transistor 20, a pixel electrode 36 and a wall 40 which are formed on the insulating substrate 10, and a hole injecting layer 51 formed in the pixel electrode exposing region 45. Then, the light emitting layer 52 is required to be formed on the hole injecting layer 51. The substrate 6 may be manufactured by a known method, and thus a detailed description thereof will be omitted.

The hole injecting layer 51 may be formed by an ink-jetting method or by the nozzle coater 200 of the exemplary embodiment of an apparatus 100. In one exemplary embodiment the hole injecting layer 51 and the light emitting layer 52 may be formed by the nozzle coater 200 of the exemplary embodiment of an apparatus 100, and in such an exemplary embodiment the processes of dropping the inks 55 and 56 are substantially the same.

In a subsequent step S201, the sub-nozzle coaters 220, 230 and 240 of the nozzle coater 201 are arranged in the first direction and the intervals therebetween are adjusted using the equation (2).

Next, at block S301 the sub-nozzle coaters 220, 230 and 240 successively drop the ink 56 including a light emitting layer forming material onto the plurality of pixel electrode exposing regions 45, while moving along the second direction.

The method of dropping the ink 56 successively to the entire pixel electrode exposing regions 45 on the substrate 6 is substantially the same as that described according to the first exemplary embodiment illustrated in FIG. 9.

At block S401, the ink 56 is dried, thereby completing the exemplary embodiment of a method for manufacturing the display device using the second exemplary embodiment of an apparatus 101.

The exemplary embodiments described above may be modified variously. In the above exemplary embodiments, a display device using an OLED is described as an example. However, the present invention is not limited thereto; alternative exemplary embodiments include other display devices, such as liquid crystal displays (“LCDs”), comprising a color filter manufactured by a nozzle coater would also be within the scope of these exemplary embodiments.

As described above, the present invention provides exemplary embodiments of an apparatus and exemplary embodiments of a method for manufacturing a display device, wherein the method and apparatus are capable of quickly and accurately forming a certain material layer in a predetermined region of a substrate.

Although a few exemplary embodiments of the present invention have been shown and described, it will be appreciated by those skilled in the art that changes may be made in these exemplary embodiments without departing from the principles and spirit of the present invention, the scope of which is defined in the appended claims and their equivalents.

What is claimed is:

1. An apparatus for manufacturing a display device which includes an insulating substrate and a plurality of sub-pixels provided in a substantially matrix shape on the insulating substrate, each pixel having a pixel electrode exposing region, the apparatus comprising:
a nozzle coater which includes a plurality of sub-nozzle coaters arranged substantially in a row along a predetermined first direction and which drops ink onto the pixel electrode exposing region while moving along a second direction substantially perpendicular to the first direction; and
an interval adjusting part which adjusts an interval between the sub-nozzle coaters.

2. The apparatus according to claim 1, wherein a plurality of gate lines and data lines are insulated from and intersect each other on the substrate, the first direction is substantially parallel to a lengthwise direction of the gate lines, and the second direction is substantially parallel to a lengthwise direction of the data lines.

3. The apparatus according to claim 2, wherein the sub-nozzle coaters drop ink including an organic layer forming material onto the pixel electrode exposing region.

4. The apparatus according to claim 3, wherein the organic layer forming material includes one of a hole injecting layer forming material, a hole transfer layer forming material and an electron transfer layer forming material.

5. The apparatus according to claim 2, wherein the nozzle coater comprises:
a first sub-nozzle coater which drops a first ink including an organic red light emitting layer forming material;
a second sub-nozzle coater which drops a second ink including an organic green light emitting layer forming material; and
a third sub-nozzle coater which drops a third ink including an organic blue light emitting layer forming material.

6. The apparatus according to claim 1, wherein the interval adjusting part adjusts the interval between the sub-nozzle coaters according to the equation d=a×m±b,
wherein d is the interval between the sub-nozzle coaters, a is a length of the sub-pixels in the first direction, m is a natural number greater than 2; and b is less than about 40% of the length of one of the sub-pixels in the first direction.

7. The apparatus according to claim 1, wherein the interval adjusting part adjusts the interval between the sub-nozzle coaters according to the equation d=3a×n+c,
wherein d is the interval between the sub-nozzle coaters, a is a length of the sub-pixels in the first direction, n is a natural number, and c is about 80% to about 120% of the interval between central points of adjacent pixel electrode exposing regions in the first direction.

8. The apparatus according to claim 5, wherein the interval adjusting part adjusts the interval between the sub-nozzle coaters according to the equation, d=3a×n+c,
wherein d is the interval between the sub-nozzle coaters, a is the length of the sub-pixels in the first direction, n is a natural number, and c is about 80% to about 120% of the interval between central points of adjacent pixel electrode exposing regions in the first direction.

9. The apparatus according to claim 6, wherein the interval adjusting part adjusts the interval between the sub-nozzle coaters to dispose the sub-nozzle coaters within 20% of a width of the sub-pixel from central positions of the sub-pixels in the first direction.

10. The apparatus according to claim 1, wherein the interval adjusting part comprises a body and a extending part, a first portion of the extending part is accommodated in the body, a second portion of the extending part is connected to one of the sub-nozzle coaters and the extending part is extendable from the body.

11. The apparatus according to claim 10, wherein the sub-nozzle coaters comprise at least a first sub-nozzle coater and a second sub-nozzle coater, the first sub-nozzle coater is connected to the body, the second sub-nozzle coater is connected to the body and the extending part extends along the first direction.

12. A method for manufacturing a display device, the method comprising:
providing a substrate which includes an insulating substrate and a plurality of sub-pixels disposed substantially in a matrix on the insulating substrate and each sub-pixel having a pixel electrode exposing region;
arranging a plurality of sub-nozzle coaters in a row along a predetermined first direction;
adjusting an interval between the sub-nozzle coaters; and
dropping ink successively from the plurality of sub-nozzle coaters onto the pixel electrode exposing region while the sub-nozzle coaters move along a second direction substantially perpendicular to the first direction.

13. The method according to claim 12, wherein a plurality of gate lines and data lines are insulated from and intersect each other on the substrate, the first direction is substantially parallel to a lengthwise direction of the gate lines, and the second direction is substantially parallel to a lengthwise direction of the data lines.

14. The method according to claim 12, wherein the dropping ink from the plurality of sub-nozzle coaters includes dropping an organic layer forming material onto the pixel electrode exposing region.

15. The method according to claim 14, wherein the dropping an organic layer forming material further comprises dropping one of a hole injecting layer forming material, a hole transfer layer forming material, and an electron transfer layer forming material.

16. The method according to claim 12, wherein the plurality of sub-nozzle coaters comprises:
a first sub-nozzle coater which drops a first ink including an organic red light emitting layer forming material;
a second sub-nozzle coater which drops a second ink including an organic green light emitting layer forming material;
and a third sub-nozzle coater which drops a third ink including an organic blue light emitting layer forming material.

17. The method according to claim 12, wherein the adjusting an interval between the sub-nozzle coaters further comprises:
adjusting the interval between the sub-nozzle coaters according to the equation d=a×m±b,
wherein d is the interval between the sub-nozzle coaters, a is a length of the sub-pixels in the first direction, m is a natural number greater than 2, and b is less than about 40% of the length of the sub-pixels in the first direction.

18. The method according to claim 12, wherein adjusting an interval between the sub-nozzle coaters further comprises:
adjusting the interval between the sub-nozzle coaters according to the equation d=3a×n+c,
wherein d is the interval between the sub-nozzle coaters, a is a length of the sub-pixels in the first direction, n is a natural number, and c is about 80% to about 120% of the interval between central points of adjacent pixel electrode exposing regions in the first direction.

19. The method according to claim 16, wherein adjusting an interval between the sub-nozzle coaters further comprises:
adjusting the interval between the sub-nozzle coaters according to the equation d=3a×n+c,
wherein d is the interval between the sub-nozzle coaters, a is a length of the sub-pixels in the first direction, n is a natural number, and c is about 80% to about 120% of the interval between central points of adjacent pixel electrode exposing regions in the first direction.

20. The method according to claim 17, wherein the adjusting an interval between the sub-nozzle coaters further comprises disposing the central positions of the sub-nozzle coaters within 20% of a width of the sub-pixel from central positions of the sub-pixels in the first direction.
